(19) United States
(12) Patent Application Publication
(10) Pub. No.: US 2011/0012020 A1
(43) Pub. Date: Jan. 20, 2011

(54) X-RAY DETECTOR AND METHOD FOR FABRICATING THE SAME

(76) Inventors: Zhu WU, North York (CA); Fengchao ZHANG, Beijing (CN)

Correspondence Address: PATRICK W. RASCHE (20459);ARMSTRONG TEASDALE LLP, 7700 Forsyth Boulevard, Suite 1800, St. Louis, MO, 63105, US

(21) Appl. No.: 12/835,901

(22) Filed: Jul. 14, 2010

(30) Foreign Application Priority Data
Jul. 16, 2009 (CN) 200910160773.5

(51) Int. Cl. G01T 1/20; H01L 21/30

(52) U.S. Cl. 250/366; 250/361 R; 438/69; 257/E21.211

(57) ABSTRACT

An X-ray detector for detecting X-ray comprises a photodetector and a scintillator layer formed of a fluorescent material coated on a light receiving surface of the photodetector, the fluorescent material converting X-ray into light.

### CROSS REFERENCE TO RELATED APPLICATIONS

This application claims the benefit of Chinese Patent Application No. 200910160773.5 filed Jul. 16, 2009, which is hereby incorporated by reference in its entirety.

### BACKGROUND OF THE INVENTION

Embodiments described herein relate to an X-ray detector and a method for fabricating the same. Particularly, embodiments described herein are concerned with an X-ray detector wherein X-ray is converted to light by a scintillator and the light is detected by a photodetector, as well as a method for fabricating such an X-ray detector.

There is known an X-ray detector wherein X-ray is converted to light by a scintillator and the light is detected by a photodetector. This type of an X-ray detector for an X-ray imaging apparatus is a panel type X-ray detector so as to permit detection of a two-dimensional distribution of X-ray and is also called a flat panel detector (FPD).

The FPD has a layer of a fluorescent material for scintillation and a layer of a photodiode array for the detection of light. As the fluorescent material there is used, for example, cesium iodide (CsI) or an acid sulfide of gadolinium (Gd₂O₂S:Tb).

In case of using cesium iodide, an acicular crystal structure of the cesium iodide is allowed to grow on the photodiode array, whereby a scintillation layer is formed (see, for example, Japanese Patent Laid-Open Publication No. 2005-308582 (Paragraph Nos. 0035-0036, FIGS. 1 and 2)).

In case of using an acid sulfide of gadolinium, a scintillation layer is formed as a ceramic layer of the acid sulfide of gadolinium and the photodiode array layer is affixed to that layer through an electrode layer and an intermediate layer (see, for example, U.S. Pat. No. 7,180,075 (column 3, line 25 to column 5, line 58, FIG. 1)).

An acid sulfide of gadolinium is used also as a fluorescent material for X-ray film sensitizing paper. In this case, the scintillation layer is formed by applying the acid sulfide of gadolinium to a plastic sheet serving as a base sheet (see, for example, Japanese Patent Laid-Open Publication No. Hei 10 (1998)-237443 (Paragraph No. 0003, FIG. 1)).

### BRIEF DESCRIPTION OF THE INVENTION

For obtaining an acicular crystal structure of cesium iodide it is necessary that crystals be allowed to grow over a long time under a strict control of conditions, thus resulting in increase of the X-ray detector fabrication cost. On the other hand, the X-ray detector comprising a ceramic layer of an acid sulfide of gadolinium and a photodiode array layer both affixed together is relatively low in cost, but it is very difficult to prevent inclusion of voids, air bubbles and foreign matters into between the layers. Therefore, deterioration of the space resolution and non-uniformity are apt to occur due to cross talk caused by scattered light. Besides, since the intermediate layer is present, the light transfer efficiency is deteriorated. The same problem is involved also in the X-ray detector fabricated by affixing sensitizing paper to a photodiode array.

Accordingly, embodiments described herein provide an X-ray detector superior in the light transfer characteristic from a scintillator to a photodetector and low in cost, as well as a method for fabricating such an X-ray detector.

For solving the above-mentioned problem, in a first aspect of the present invention there is provided an X-ray detector for detecting X-ray, the X-ray ray detector comprising a photodetector and a scintillator layer formed of a fluorescent material coated on a light receiving surface of the photodetector, the fluorescent material converting X-ray into light.

For solving the above-mentioned problem, in a second aspect of the present invention there is provided, in combination with the above first aspect, an X-ray detector wherein the fluorescent material is an acid sulfide of a rare earth element.

For solving the above-mentioned problem, in a third aspect of the present invention there is provided, in combination with the above second aspect, an X-ray detector wherein the acid sulfide of a rare earth element is an acid sulfide of gadolinium (Gd₂O₂S:Tb).

For solving the above-mentioned problem, in a fourth aspect of the present invention there is provided, in combination with the above first aspect, an X-ray detector wherein the light receiving surface of the photodetector surface-treated in advance.

For solving the above-mentioned problem, in a fifth aspect of the present invention there is provided, in combination with the above first aspect, an X-ray detector wherein a transparent insulating material is coated beforehand on the light receiving surface of the photodetector.

For solving the above-mentioned problem, in a sixth aspect of the present invention there is provided, in combination with the above first aspect, an X-ray detector wherein the photodetector has a photodiode array on the light receiving surface.

For solving the above-mentioned problem, in a seventh aspect of the present invention there is provided, in combination with the above sixth aspect, an X-ray detector wherein the photodiode array is a two-dimensional array.

For solving the above-mentioned problem, in an eighth aspect of the present invention there is provided, in combination with the above seventh aspect, an X-ray detector wherein the two-dimensional array is constituted by a thin film semiconductor.

For solving the above-mentioned problem, in a ninth aspect of the present invention there is provided, in combination with the above eighth aspect, an X-ray detector wherein the thin film semiconductor is amorphous silicon.

For solving the above-mentioned problem, in a tenth aspect of the present invention there is provided, in combination with the above first aspect, an X-ray detector wherein the fluorescent material has an X-ray transmitting protective film on a surface thereof located on the side opposite to the photodetector.

For solving the above-mentioned problem, in an eleventh aspect of the present invention there is provided a method for fabricating an X-ray detector for detecting X-ray, the method comprising the step of coating a fluorescent material on a light receiving surface of a photodetector to form a scintillation layer.

For solving the above-mentioned problem, in a twelfth aspect of the present invention there is provided, in combination with the above eleventh aspect, a method for fabricating an X-ray detector wherein the fluorescent material is an acid sulfide of a rare earth element.

For solving the above-mentioned problem, in a thirteenth aspect of the present invention there is provided, in combination with the above twelfth aspect, a method for fabricating an X-ray detector wherein the acid sulfide of a rare earth element is an acid sulfide of gadolinium (Gd₂O₂S:Tb).

For solving the above-mentioned problem, in a fourteenth aspect of the present invention there is provided, in combination with the above eleventh aspect, a method for fabricating an X-ray detector which method further comprises the step of surface-treating the light receiving surface of the photodetector prior to the step of forming the scintillation layer.

For solving the above-mentioned problem, in a fifteenth aspect of the present invention there is provided, in combination with the above eleventh aspect, a method for fabricating an X-ray detector wherein a transparent insulating material is coating on the light receiving surface of the photodetector prior to the step of forming the scintillation layer.

For solving the above-mentioned problem, in a sixteenth aspect of the present invention there is provided, in combination with the above eleventh aspect, a method for fabricating an X-ray detector wherein the photodiode has a photodiode array on the light receiving surface.

For solving the above-mentioned problem, in a seventeenth aspect of the present invention there is provided, in combination with the above sixteenth aspect, a method for fabricating an X-ray detector wherein the photodiode array is a two-dimensional array.

For solving the above-mentioned problem, in an eighteenth aspect of the present invention there is provided, in combination with the above seventeenth aspect, a method for fabricating an X-ray detector wherein the two-dimensional array is constituted by a thin film semiconductor.

For solving the above-mentioned problem, in a nineteenth aspect of the present invention there is provided, in combination with the above eighteenth aspect, a method for fabricating an X-ray detector wherein the thin film semiconductor is amorphous silicon.

For solving the above-mentioned problem, in a twentieth aspect of the present invention there is provided, in combination with the above eleventh aspect, a method for fabricating an X-ray detector which method further comprises forming an X-ray transmitting protective film on a surface of the fluorescent material on the side opposite to the photodetector.

According to the above first aspect of the present invention, since the X-ray detector for detecting X-ray comprises a photodetector and a scintillator layer formed of a florescent material for converting X-ray into light, the fluorescent material being coated on a light receiving surface of the photodetector prior to the step of forming the scintillation layer, it is possible to provide an X-ray detector superior in the light transfer characteristic from the scintillator to the photodetector and low in cost.

According to the above eleventh aspect of the present invention, since the method for fabricating an X-ray detector for detecting X-ray has the step of coating a fluorescent material to a light receiving surface of a photodetector to form a scintillation layer, it is possible to provide an X-ray detector fabricating method superior in the light transfer characteristic from the scintillator to the photodetector and low in cost.

According to the above second or twelfth aspect of the present invention, since the fluorescent material an acid sulfide of a rare earth element, it is easy to form the scintillation layer.

According to the above third or thirteenth aspect of the present invention, since the acid sulfide of a rare earth element is an acid sulfide of gadolinium (Gd₂O₂S:Tb), the stability of scintillation is high.

According to the above fourth or fourteenth aspect of the present invention, since the light receiving surface of the photodetector is surface-treated in advance, the adhesion thereof to the fluorescent material is satisfactory.

According to the above fifth or fifteenth aspect of the present invention, since a transparent insulating material is coated beforehand on the light receiving surface of the photodetector, the isolation from the fluorescent material is satisfactory.

According to the above sixth or sixteenth aspect of the present invention, since the photodetector has a photodiode array on the light receiving surface, it is possible to detect distribution of fluorescence.

According to the above seventh or seventeenth aspect of the present invention, since the photodiode array is a two-dimensional array, it is possible to detect a two-dimensional distribution of fluorescence.

According to the above eighth or eighteenth aspect of the present invention, since the two-dimensional array is constituted by a thin film semiconductor, there are attained high speed and low power consumption.

According to the above ninth or nineteenth aspect of the present invention, since the thin film semiconductor is amorphous silicon, it is easy to form a thin film.

According to the above tenth or twentieth aspect of the present invention, since the fluorescent material has an X-ray transmitting protective film on a surface thereof located on the side opposite to the photodetector, there is attained a high environmental resistance.

### BRIEF DESCRIPTION OF THE DRAWINGS

FIG. 1 is a view showing an appearance of an X-ray imaging apparatus.

FIG. 2 is a view showing in what state the X-ray imaging apparatus is moved.

FIG. 3 is a view showing in what state a patient is radiographed by the X-ray imaging apparatus.

FIG. 4 is a view showing a basic construction of a detector panel.

FIG. 5 is a view showing an internal construction of the detector panel.

FIG. 6 is a view showing a schematic construction of an X-ray detector.

FIG. 7 is a diagram showing fabrication steps for the X-ray detector.

FIG. 8 is a view showing the X-ray detector in a fabrication step.

FIG. 9 is a view showing the X-ray detector in another fabrication step.

FIG. 10 is a view showing the X-ray detector in a further fabrication step.

### DETAILED DESCRIPTION OF THE INVENTION

The best mode for carrying out the present invention will be described in detail hereinunder with reference to the drawings. The present invention is not limited to the best mode for carrying out the invention.

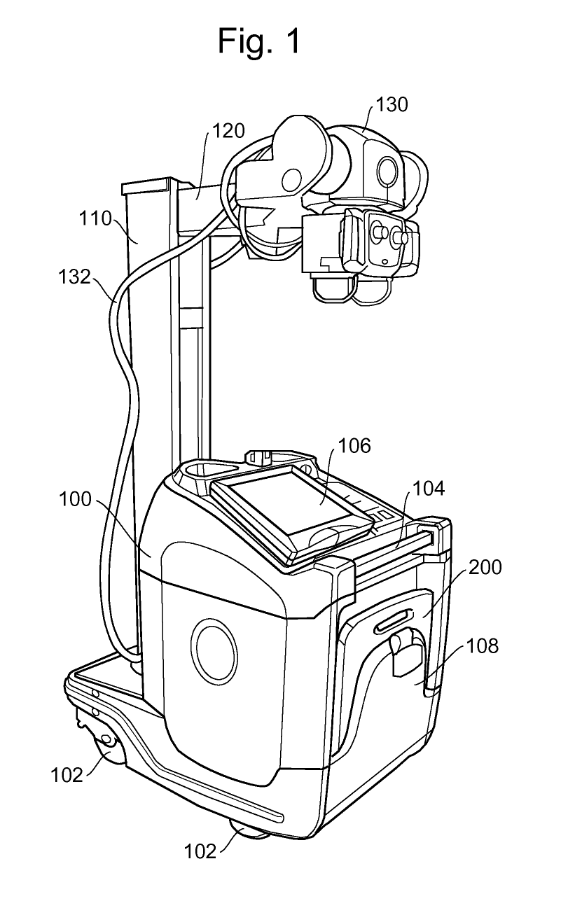

FIG. 1 shows an appearance of an X-ray imaging apparatus. As shown in FIG. 1, this X-ray imaging apparatus includes a system console 100. The system console 100 is a box-shaped, generally rectangular parallelepiped-like structure, in the interior of which is accommodated an electronic circuit to control radiographing.

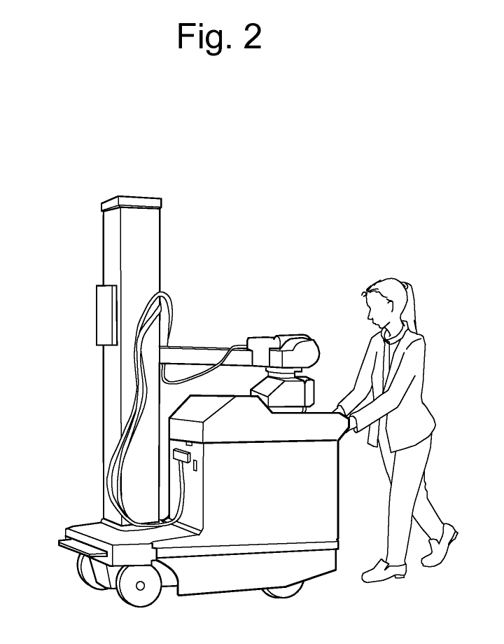

The system console 100 is provided at lower positions with casters 102 for movement and is further provided at an upper position with a handle 104 for hand-push. As shown in FIG. 2, this X-ray imaging apparatus is a movable X-ray imaging apparatus capable of being moved freely.

An upper surface of the system console 100 is constituted by an operating panel 106 and is provided with man-machine communication devices such as, for example, a graphic display and a keyboard.

A vertical column 110 is provided behind the system console 100 and an X-ray irradiator 130 is attached to a front end of an arm 120 which extends horizontally from the column 110. The X-ray irradiator 130 generates X-ray under a high voltage which is supplied to the system console 100 though a cable 132.

The X-ray irradiator 130 can change its direction at the front end of the arm 120. The arm 120 is vertically movable along the column 110 and the column 110 can spin about a longitudinal axis.

The X-ray imaging apparatus includes a detector panel 200. The detector panel 200 is a generally rectangular plate-like structure and it is constituted separately from the system console 100 and is portable. When radiographing is not performed, the detector panel 200 is received within a receptacle portion 108 formed on a front side of the system console 100, while when radiographing is performed, it is taken out from the receptacle portion 108 and is used. The detector panel 200 is a so-called FPD.

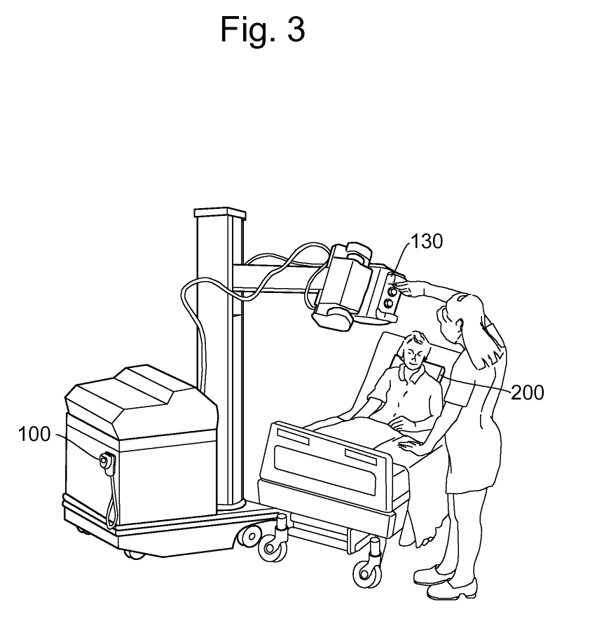

FIG. 3 shows in what state the X-ray imaging apparatus is used. As shown in FIG. 3, the X-ray imaging apparatus is used in a sickroom. Radiographing is performed for example by applying the detector panel 200 to the back side of a patient and radiating X-ray from the front side with use of the X-ray irradiator 130. An X-ray signal detected by the detector panel 200 is transmitted to the system console 100 in a wireless manner.

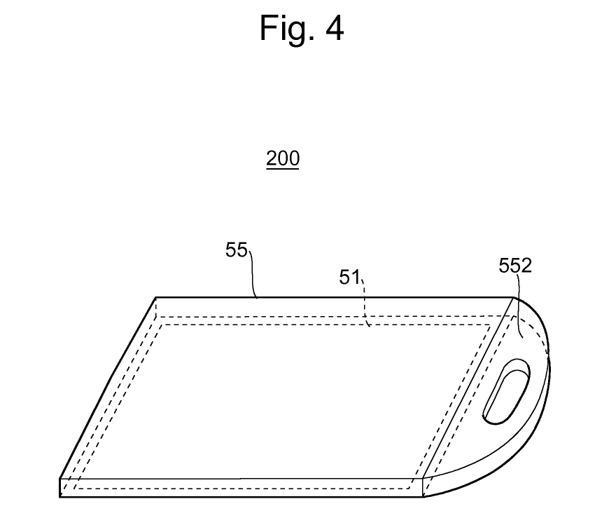

FIG. 4 shows a basic construction of the detector panel 200. As shown in FIG. 4, the detector panel 200 comprises a box-like case 55 and a rectangular plate-like X-ray detector assembly 51 accommodated within the case 55. An upper portion of the X-ray detector assembly 51, which upper portion is opposed to an X-ray detecting surface of the X-ray detector assembly 51, is formed using an X-ray transmitting material. The case 55 has a handle 552 at one end portion thereof

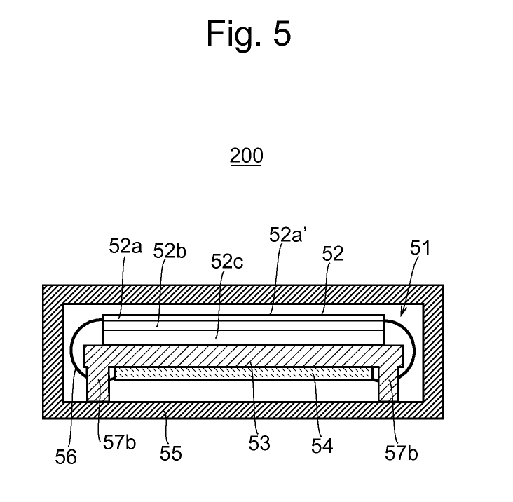

FIG. 5 schematically shows an example of an internal construction of the detector panel 200. FIG. 5 is a vertical sectional view of the detector panel 200. As shown in FIG. 5, the X-ray detector assembly 51 is made up of an X-ray detector 52, a supporting substrate 53 and an electric circuit board 54. The X-ray detector 52 is disposed on a surface of the supporting substrate 53, while the electric circuit board 54 is disposed on a back side of the supporting substrate 53, and both are connected together electrically through a flexible circuit board 56.

The X-ray detector 52 is a laminate of a scintillator layer 52a, a photoelectric conversion layer 52b and a glass substrate 52c. The scintillator layer 52a converts X-ray into light and the photoelectric conversion layer 52b converts the light into an electric signal. Then, the electric signal is inputted to the electric circuit board 54 through the flexible circuit board 56. The photoelectric conversion layer 52b is an example of the photodetector in the present invention.

An electric circuit is mounted on the electric circuit board 54. The electric circuit is an interface for the system console 100 and it converts the inputted signal into digital data and transmits the digital data to the system console 100 in a wireless manner.

Four spacers 57b are formed on the back side of the supporting substrate 53. The spacers 57b are integral with the supporting substrate 53. With the spacers 57b, the supporting substrate 53 stands up itself on an inner bottom wall of the case 55. Lower ends of the spacers 57b are fixed to the inner bottom wall of the case 55 by bonding or with screws.

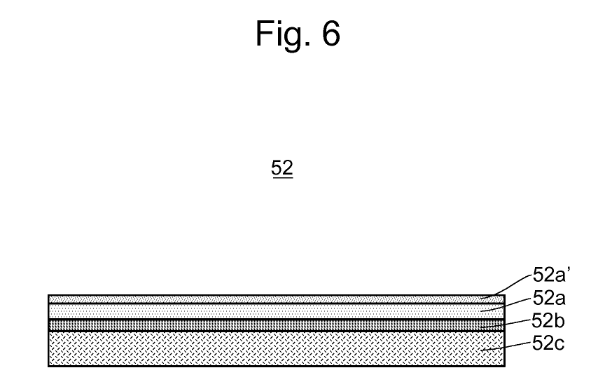

FIG. 6 shows the construction of the X-ray detector 52 schematically. The X-ray detector 52 is an example of the best mode for carrying out the invention. With the construction of the X-ray detector 52 there is shown an example of the best mode for carrying out the invention with respect to the X-ray detector.

In the X-ray detector 52, as shown in FIG. 6, the photoelectric conversion layer 52b is formed on the glass substrate 52c, the scintillator layer 52a is formed on the photoelectric conversion layer 52b, and a protective layer 52a′ is formed on the scintillator layer 52a.

The photoelectric conversion layer 52b is constituted by a two-dimensional array of photoelectric conversion elements. The two-dimensional array of the photoelectric conversion elements is a well-known active matrix. The active matrix is constituted by a thin film semiconductor. As the thin film semiconductor there is used, for example, amorphous silicon.

In the active matrix, a photodiode for photoelectric conversion, a capacitor for the storage of an electric current outputted from the photodiode, and a TFT (thin film transistor) for outputting the electric charge of the capacitor, constitute one unit. One unit in the active matrix corresponds to one pixel of an X-ray image.

The scintillator layer 52a is constituted using, for example, an acid sulfide of gadolinium (Gd₂O₂S:Tb) as a fluorescent material. The fluorescent material is not limited to the acid sulfide of gadolinium, but may be an acid sulfide of any other suitable rare earth element, e.g., yttrium (Y) or lanthanum (La).

The protective layer 52a′ is for protecting the scintillator layer 52a from the external environment. As the material of the protective layer 52a′ there is used, for example, a plastic material superior in all of X-ray transmittance, mechanical strength, resistance to electrostatic damage (ESD) and resistance to electromagnetic interference (EMI/EMC).

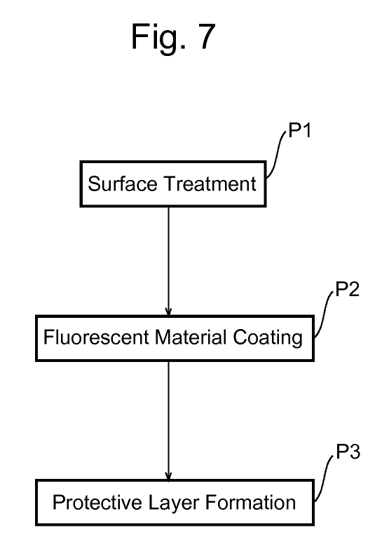

FIG. 7 shows main steps of a process for fabricating the X-ray detector 52. This process is an example of the best mode for carrying out the invention. With this process there is shown an example of the best mode for carrying out the invention with respect to the method for fabricating the X-ray detector.

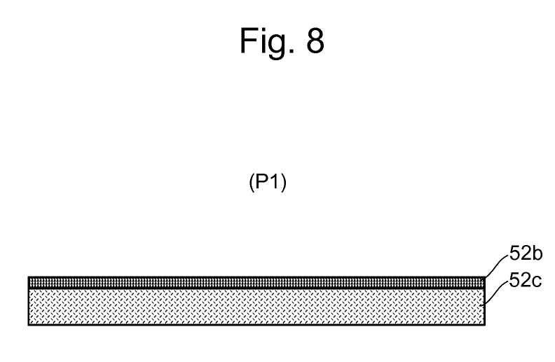

As shown in FIG. 7, a surface treatment is performed in step P1. As shown in FIG. 8, the surface treatment is performed for the photoelectric conversion layer 52b formed on the glass substrate 52c. The formation of the photoelectric conversion layer 52b in the glass substrate 52c has been completed in a step preceding this step.

The surface treatment is performed for activating the surface of the photoelectric conversion layer 52b and thereby strengthening the bonding thereof to the fluorescent material to be coated in the next step. The surface treatment may be omitted if the surface of the photoelectric conversion layer 52b is already sufficiently active.

In step P2 the fluorescent material is coated. The coating of the fluorescent material is performed by coating fine particles of the fluorescent material, e.g., an acid sulfide of gadolinium, dispersed in a suitable organic binder to the surface of the photoelectric conversion layer 52b. The fluorescent material thus coated is then solidified by drying.

The coating step P2 is the same as the step of coating a fluorescent material onto base paper in a sensitizing paper fabricating process. Therefore, the coating of the fluorescent material to the photoelectric conversion layer 52b can be done by using the same equipment and process.

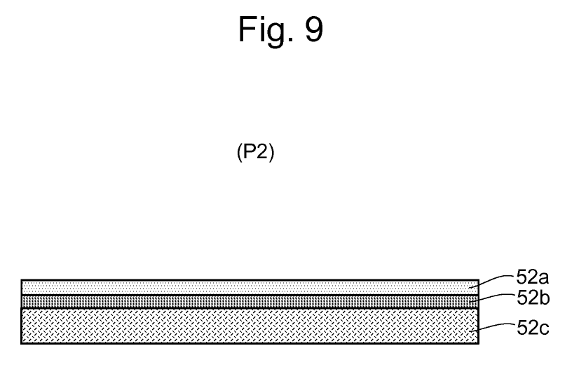

In this way the scintillator layer 52a is formed on the photoelectric conversion layer 52b, as shown in FIG. 9. The scintillator layer 52a is in a directly coupled state to the photoelectric conversion layer 52b. Since the formation of the scintillator layer 52a is performed by the coating of the fluorescent material, it is easy to prevent the inclusion of voids, air bubbles and foreign matters into between the layers.

Prior to the coating of the fluorescent material there may be formed an insulating film on the surface of the photoelectric conversion layer 52b. The formation of the insulating film is performed by coating a transparent insulating material extremely thinly to the surface of the photoelectric conversion layer 52b. Since the formation of the insulating film is performed by the coating of the insulating material, it is easy to prevent the inclusion of voids, air bubbles and foreign matters into between the layers.

As a result, an electric isolation between the photoelectric conversion layer 52b and the scintillator layer 52a is improved. At this time, the scintillator layer 52a is not in a directly coupled state to the photoelectric conversion layer 52b, but optically it can be regarded as being in a directly coupled state because the insulating film is extremely thin and transparent.

In step P3 there is formed a protective layer. The formation of the protective layer is performed by coating a suitable material to the surface of the scintillator layer 52a. The formation of the protective layer can also be conducted in the same way as in the protective film formation in the sensitizing paper fabricating process.

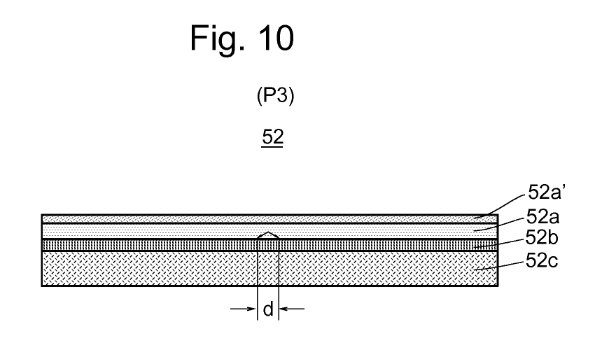

In this way, as shown in FIG. 10, there is obtained an X-ray detector 52 wherein the photoelectric conversion layer 52b, scintillator layer 52a and protective layer 52a′ are stacked in this order on the glass substrate 52c.

In the X-ray detector 52 thus fabricated, since the scintillator layer 52a and the photoelectric conversion layer 52b are directly coupled with each other, the transfer of light from the scintillator layer 52a to the photoelectric conversion layer 52b can be done in an extremely efficient manner. As a result, the sensitivity of the X-ray detector 52 is improved and hence it is possible to decrease the X-ray exposure quantity of a patient during radiographing.

Since the scintillator layer 52a and the photoelectric conversion layer 52b are directly coupled with each other, the transfer of light from the scintillator layer 52a to the photoelectric conversion layer 52b is uniform throughout the whole surface of the X-ray detector 52.

Moreover, since voids, air bubbles and foreign matters are not present between the scintillator layer 52a and the photoelectric conversion layer 52b, cross talk caused by scattered light diminishes to a great extent and there is attained an improvement not only in space resolution (MTF) but also in uniformity thereof

For example, given that the thickness of the scintillator layer 52a is 100 μm, the range, d, of cross talk caused by scattered light is 200 μm. This corresponds to two pixels in terms of pixel and thus the range of cross talk is not greater than two pixels.

With such a high space resolution and uniformity thereof, as well as uniformity of the transfer of light from the scintillator layer 52a to the photoelectric conversion layer 52b, the X-ray detector 52 can afford an X-ray image of high quality.

Further, since a bonding layer for affixing the scintillator layer 52a and the photoelectric conversion layer 52b with each other or an intermediate layer is not present between both layers 52a and 52b, there is no fear of occurrence of deterioration in reliability based on the coefficient of thermal expansion (CTE) of such a bonding or intermediate layer. Besides, the fabrication cost is low.

1. An X-ray detector for detecting X-rays, comprising:
a photodetector comprising a light receiving surface; and
a scintillator layer formed of a fluorescent material coated on the light receiving surface of the photodetector, the fluorescent material configured to convert X-rays into light.

2. An X-ray detector according to claim 1, wherein the fluorescent material is an acid sulfide of a rare earth element.

3. An X-ray detector according to claim 2, wherein the acid sulfide of a rare earth element is an acid sulfide of gadolinium (Gd2O2S:Tb).

4. An X-ray detector according to claim 1, wherein the light receiving surface of the photodetector is surface-treated in advance of the scintillator layer being applied.

5. An X-ray detector according to claim 1, further comprising a transparent insulating material that is coated beforehand to the light receiving surface of the photodetector.

6. An X-ray detector according to claim 1, wherein the photodetector comprises a photodiode array on the light receiving surface.

7. An X-ray detector according to claim 6, wherein the photodiode array is a two-dimensional array.

8. An X-ray detector according to claim 7, wherein the two-dimensional array comprises a thin film semiconductor.

9. An X-ray detector according to claim 8, wherein the thin film semiconductor is amorphous silicon.

10. An X-ray detector according to claim 1, wherein the scintillator layer comprises a first side adjacent the photodetector and a second side opposite the first side, and wherein the fluorescent material comprises an X-ray transmitting protective film on a surface thereof located on the second side of the scintillator layer.

11. A method for fabricating an X-ray detector for detecting X-ray, comprising the-step-of coating a fluorescent material to a light receiving surface of a photodetector to form a scintillation layer.

12. A method for fabricating an X-ray detector according to claim 11, wherein the fluorescent material is an acid sulfide of a rare earth element.

13. A method for fabricating an X-ray detector according to claim 12, wherein the acid sulfide of a rare earth element is an acid sulfide of gadolinium (Gd2O2S:Tb).

14. A method for fabricating an X-ray detector according to claim 11, further comprising surface-treating the light receiving surface of the photodetector prior to forming the scintillation layer.

15. A method for fabricating an X-ray detector according to claim 11, further comprising coating the light receiving surface of the photodetector with a transparent insulating material prior to forming the scintillation layer.

16. A method for fabricating an X-ray detector according to claim 11, wherein the photodetector has a photodiode array on the light receiving surface.

17. A method for fabricating an X-ray detector according to claim 16, wherein the photodiode array is a two-dimensional array.

18. A method for fabricating an X-ray detector according to claim 17, wherein the two-dimensional array is constituted by a thin film semiconductor.

19. A method for fabricating an X-ray detector according to claim 18, wherein the thin film semiconductor is amorphous silicon.

20. A method for fabricating an X-ray detector according to claim 11, further comprising forming an X-ray transmitting protective film on a surface of the fluorescent material on a side of the fluorescent material that is opposite to the photodetector.
